(19) United States
(12) Patent Application Publication
(10) Pub. No.: US 2023/0154754 A1
(43) Pub. Date: May 18, 2023

(54) LOSS PREVENTION DURING ATOMIC LAYER DEPOSITION

(71) Applicant: Lam Research Corporation, Fremont, CA (US)

(72) Inventors: Jason Alexander VARNELL, Tigard, OR (US); Joseph R. ABEL, West Linn, OR (US); Douglas Walter AGNEW, Portland, OR (US)

(21) Appl. No.: 17/995,461

(22) PCT Filed: Apr. 9, 2021
(86) PCT No.: PCT/US2021/026658

§ 371 Date: Oct. 4, 2022

Related U.S. Application Data
(60) Provisional application No. 63/008,123, filed on Apr. 10, 2020.

(51) Int. Cl. H01L 21/033; C23C 16/40; C23C 16/455; C23C 16/04

(52) U.S. Cl. CPC H01L 21/0337; C23C 16/402; C23C 16/45542; C23C 16/045; H01L 21/0332

(57) ABSTRACT

Methods of depositing silicon oxide on carbon-based films on a substrate involve adsorbing a silicon-containing reactant on the substrate surfaces, generating oxygen radicals from N2O, and exposing the adsorbed silicon-containing reactant to the oxygen radicals to form a silicon oxide film. In some embodiments, the carbon-based films form features having sidewalls. The methods result in low carbon loss and substantially vertical sidewalls. Embodiments of the methods are performed at high temperatures that facilitate high quality deposition.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

During integrated circuit (IC) fabrication, silicon oxide films may be deposited on carbon-based layers. For example, multiple patterning techniques such as self-aligned double patterning (SADP) may use silicon oxide layers on carbon-based cores. In such techniques, maintaining pattern uniformity can be challenging.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods of depositing silicon oxide on carbon-based films on a substrate involve adsorbing a silicon-containing reactant on the substrate surfaces, generating oxygen radicals from N₂O, and exposing the adsorbed silicon-containing reactant to the oxygen radicals to form a silicon oxide film. In some embodiments, the carbon-based films form features having sidewalls. The methods result in low carbon loss and substantially vertical sidewalls. Embodiments of the methods are performed at high temperatures that facilitate high quality deposition. One aspect of the disclosure relates to a method including: providing a substrate having carbon-based features thereon, the carbon-based features having exposed sidewall surfaces and being separated by gaps; depositing a silicon oxide liner film in the gaps by a plasma enhanced atomic layer deposition (PEALD) process that includes multiple cycles of (a) introducing a silicon-containing reactant into a reaction chamber having the substrate therein, and allowing the first reactant to adsorb onto substrate surfaces; (b) generating oxygen radicals from N₂O, and (c) exposing the adsorbed silicon-containing reactant to the oxygen radicals to form the silicon oxide liner film in the gaps, where the substrate temperature during deposition is at least 100° C.

In some embodiments, the method involves, after depositing the silicon oxide liner film in the gaps, depositing silicon oxide film in the gaps by PEALD using a reaction between the silicon-containing reactant and oxygen (O₂). In some embodiments, the method involves, at least partially filling the gaps with silicon oxide by PEALD using a reaction between the silicon-containing reactant and N₂O.

In some embodiments, the substrate temperature during deposition is at least 150° C. In some embodiments, the substrate temperature during deposition is at least 200° C.

In some embodiments, the method involves during the PEALD process, periodically exposing the substrate to an inhibition plasma. In some such embodiments, the inhibition plasma is generated from an inhibition gas generated from one of a fluorine-containing compound, molecular nitrogen (N₂), argon (Ar), helium (He), molecular hydrogen (H₂), ammonia (NH₃), an amine, a diol, an aminoalcohol, a thiol, or a combination thereof.

In some embodiments, the silicon-containing reactant is an aminosilane. In some such embodiments, the aminosilane has two or more amine groups attached to the central silicon atom.

Another aspect of the disclosure relates to a method including (a) providing a substrate having carbon-based features thereon, the carbon-based features having exposed sidewall surfaces and being separated by gaps; (b) performing multiple cycles of a (i) introducing a silicon-containing reactant into a reaction chamber having the substrate therein and allowing the first reactant to adsorb onto substrate surfaces, (ii) generating oxygen radicals from N₂O, and (iii) exposing the adsorbed silicon-containing reactant to the oxygen radicals to form a silicon oxide liner film in the gaps; and (c) after (b) exposing the gaps to an inhibition plasma.

In some embodiments, the method includes: (d) after (c), filling the gap with a silicon oxide film. In some such embodiments, (d) includes using a plasma generated from oxygen (O₂) as an oxidant. In some embodiments, (d) includes using a plasma generated from N₂O and O₂ as an oxidant. In some embodiments, (d) is performed at a different substrate temperature than (b). In some embodiments, (d) is performed at the same substrate temperature as (b).

In some embodiments, the method involves after (c), repeating (b). In some embodiments, the method involves after (c), repeating (b) and (c) one or more times. In some embodiments, the substrate temperature throughout the process is at least 100° C. In some embodiments, the substrate temperature throughout the process is at least 150° C. In some embodiments, the substrate temperature throughout the process is at least 200° C.

These and other aspects of the disclosure are described further below with reference to the drawings.

### BRIEF DESCRIPTION OF THE DRAWINGS

FIG. 1 is a schematic depiction of carbon-based features with no material loss compared to those with material loss.

FIGS. 2-4 are process flow diagrams of methods accordance with disclosed embodiments.

FIGS. 5A-5D are schematic depictions of a patterning scheme that uses a method in accordance with disclosed embodiments.

FIG. 6 is a schematic depiction of carbon-based features illustrating locations of critical dimension (CD) measurements.

FIG. 7 is a table showing mean normalized CD measurements after atomic layer deposition processes at various temperatures and using various oxidants (O₂ and N₂O).

FIG. 8 is a plot comparing CD after ALD using O₂ with CD after ALD using N₂O.

FIG. 9 is an illustration of a process station that may that may be used for performing operations in accordance with disclosed embodiments.

FIG. 10 is an illustration of a multi-station apparatus that may be used for performing operations in accordance with disclosed embodiments.

FIG. 11 is a block diagram of a processing system suitable for the deposition processes described herein in accordance with certain embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Fabrication of semiconductor devices typically involves depositing one or more thin films in an integrated manufacturing process and may include patterning steps. Multiple patterning techniques are used to fabricate advanced integrated circuits, such as those with smaller features or higher aspect ratios, or down to 2× or 1× nm nodes. The term “1×” node means a process node between 10 nm and 19 nm and the term “2×” node means a process node between 20 nm and 29 nm. An example of multiple patterning is self-aligned double patterning (SADP), which produces double the number of features of a pattern formed by conventional lithography. As the devices become smaller, narrower half-pitch features may be attained using advanced multiple patterning techniques, such as quadruple patterning, or “quad patterning.”

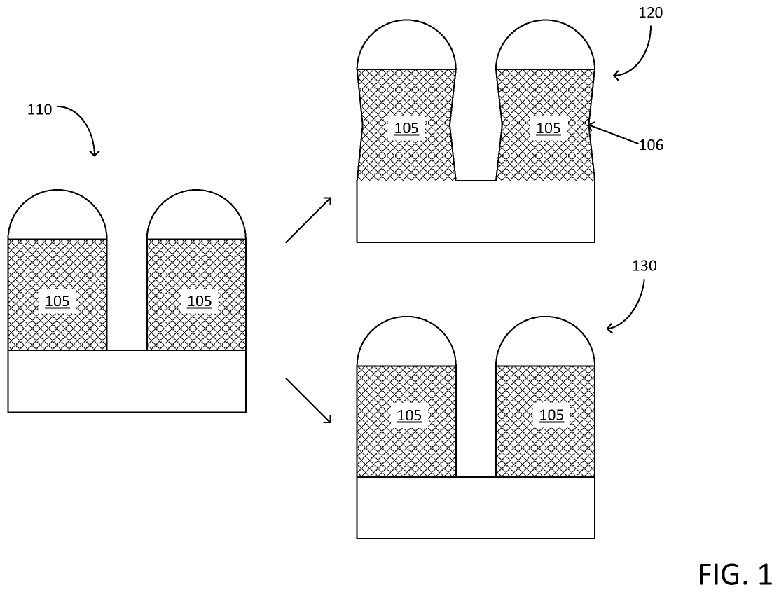

During multiple patterning techniques, a silicon oxide film may be deposited on a carbon-based layer. In some techniques, for example, silicon dioxide films deposited on carbon-based cores are used to form spacers around the cores. By depositing two spacers on each carbon-based core, the patterning density can be doubled. In this and other integration processes in which silicon oxide films are deposited on the sidewalls of carbon-based features, it can be challenging to prevent material loss from the carbon-based film. Referring to FIG. 1, for example, at 110, an incoming structure is shown including carbon-based features 105. These can be for example, patterned features formed as part of a patterning technique and may be hard mask material. Examples of carbon-based materials include amorphous carbon and polymeric carbon-based films such as spin-on carbon. Such carbon-based films may have some mix of polymer, cross-linkers, additives, etc. In general, the carbon-based film has over 50% (at.) carbon.

At 120, the structure is shown after having undergone a process in which the carbon-based features 105 are damaged. In particular, material is lost from the sidewalls 106 such that they are no longer vertical. Although the silicon oxide film is not depicted in FIG. 1 for ease of description, material loss can result from atomic layer deposition (ALD) of silicon dioxide on the carbon-based features. Provided herein are methods of depositing silicon oxide films by ALD that result in low loss and substantially vertical sidewalls, as shown at 130. Moreover, as described further below, embodiments of the methods are performed at high temperatures that facilitate high quality deposition.

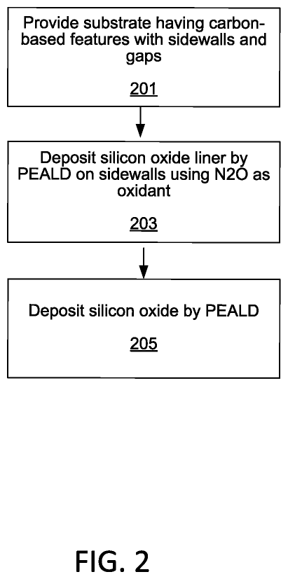

FIG. 2 shows an example of a process flow that may be used to deposit silicon oxide films on carbon-based layers. The process begins at an operation 201 in which a substrate having carbon-based features with sidewalls and gaps is provided. The substrate may be a semiconductor substrate, such as 300 mm or 450 mm silicon wafer, that is undergoing IC fabrication. One or more layers or dielectric, conductive, and/or semiconducting materials are typically deposited on the semiconductor substrate. In the particular example of FIG. 2, there are also carbon-based features having sidewalls with gaps between the features. An example is shown in FIG. 1 at 110, with carbon-based features 105 on a substrate and a gap between the carbon-based features. The sidewalls of the carbon-based features are exposed.

While the example of FIGS. 1 and 2 are of carbon-based features, the deposition methods described herein may also be used on other oxidation-sensitive materials, such as cobalt, germanium-antimony-tellerium, silicon, silicon-germanium, etc. Further, the methods may also be used to deposit silicon oxide layers on planar surfaces or single features.

In some embodiments, the substrate includes an initial pattern of carbon-based features, which are formed in a previous fabrication operation. The carbon-based features may be spin-on carbon features and may be referred to as a patterned hardmask layer or patterned spin-on hardmask layer. The carbon-based features may be characterized by a height, width, and one or more of feature density, pitch, or gap width. In one example, the width of each feature may be 100 nm with the gap between features about 50 nm.

The substrate is provided to a chamber capable of performing plasma-enhanced atomic layer deposition (PEALD). Further description of such chambers is provided below. Next, in an operation 203, a silicon oxide liner is deposited by PEALD using N₂O as the oxidant.

PEALD processes use surface-mediated deposition reactions to deposit films on a layer-by-layer basis in cycles. As an example, a PEALD cycle may include the following operations: (i) delivery/adsorption of a precursor, (ii) purging of the precursor from the chamber, (iii) delivery of a second reactant and plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant (for example, N₂O) is introduced to the chamber so that some of these molecules react with the first precursor adsorbed on the surface. The second reactant reacts after a source of activation such as plasma is applied temporally. The chamber may then be evacuated again to remove unbound second reactant molecules. As described above, in some embodiments the chamber may not be completely evacuated. Additional PEALD cycles may be used to build film thickness.

Examples of silicon-containing reactants that may be used are provided below. In the example of FIG. 2, the oxidant is nitrous oxide (N₂O). In some embodiments, nitrous oxide is provided as the only oxidant. That is, no other oxidant such as oxygen is provided. By using N₂O, the PEALD process can deposit a SiO₂ film without degrading the carbon.

Unlike other PEALD processes in which temperature is kept low to avoid carbon degradation, temperature is not particularly limited in the methods described herein. In some embodiments, a relatively high temperature is used to deposit good quality film and/or facilitate void free gap fill. In such embodiments, temperature may be greater than 100° C., greater than 150° C., or 190° C. In some embodiments, for example, the PEALD may be performed at 200° C. Other temperature ranges may be used, for example, greater than 100° C. and less than 300° C., or greater than 100° C. and less than 250° C., or between 150° C. and 250° C., end points included. Higher temperatures (e.g., up to 400° C.) may also be used if the thermal budget otherwise permits. The ability to operate at high temperature can be advantageous in allowing subsequent processing (e.g., dielectric deposition) without having to raise temperature in the chamber or switch to a different chamber.

HFRF power may be relatively low and may depend on the sensitivity of the carbon material. For example, a HFRF power may be between about 100 W to about 350 W per station for a 300 mm wafer. Plasma power may be scaled linearly with wafer surface area.

After operation 203, silicon oxide is deposited on the liner layer by PEALD in an operation 205. In many embodiments, operation 205 is continuation of operation 203, with the same reactants and process conditions (temperature, RF power, etc.) used. Notably, the same substrate temperature may be used in operation 205 as in operation 203. That is, because operation 203 does not damage the underlying carbon-based layer, a relatively high temperature may be used for operation 203 as well as operation 205. Operation 205 may be performed to deposit the remainder of the silicon oxide film; depending on the particular application, this may involve complete fill of the gaps between the carbon-based features or depositing silicon oxide without complete gap fill. The latter may be done to form spacers in a multiple patterning technique, for example. In some embodiments, operation 205 may involve adding oxygen (O₂) to the N₂O oxidant or switching from N₂O to O₂.

An example of how the process of FIG. 2 can integrated into a multiple patterning scheme is provided below.

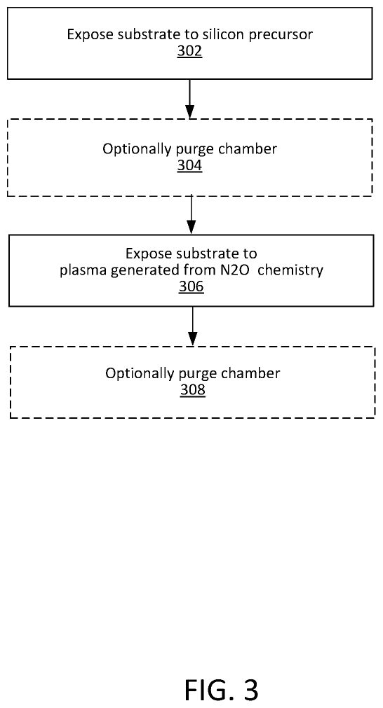

FIG. 3 presents a process flow diagram for a single PEALD cycle using N₂O that may be implemented as part of operation 203 and/or 205. In an operation 302, the substrate is exposed to a silicon-containing precursor, to adsorb the precursor onto the surface of the feature. This operation may be self-limiting. In some embodiments, the precursor adsorbs to less than all of the active sites on the surface of the feature. In an operation 304, the process chamber is optionally purged to remove any unadsorbed silicon-containing precursors. In an operation 306, the substrate is exposed to a plasma generated from N₂O to form a silicon oxide layer. A carrier gas such N₂ may be used. The species resulting from plasma generation are mostly oxygen radicals, which react with the adsorbed silicon-containing precursor layer to convert to silicon oxide, and nitrogen, which does not react. Plasmas generated from O₂ typically have a range of different oxidizing species. With N₂O, the reactive species are mostly limited to oxygen radicals. In operation 308, the process chamber is optionally purged to remove byproducts from the reaction between the silicon-containing precursor and the oxidant. Operations 302 through 308 repeated for a number of cycles to deposit silicon oxide to a desired thickness in the feature.

It should be noted that the processes described herein are not limited to a particular reaction mechanism. Thus, the process described with respect to FIG. 3 includes all oxide deposition processes that use sequential exposures to silicon-containing reactants and oxidizing plasmas, including those that are not strictly self-limiting. The process includes sequences in which one or more gases used to generate a plasma is continuously flowed throughout the process with intermittent plasma ignitions. Further, in some embodiments, thermal ALD using the described chemistries may be employed.

For depositing silicon oxide, one or more silicon-containing precursors may be used. Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Although halosilanes, particularly fluorosilanes, may form reactive halide species that can etch silicon materials when a plasma is struck, a halosilane may not be introduced to the chamber when a plasma is struck in some embodiments, so formation of a reactive halide species from a halosilane may be mitigated. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

The PEALD cycle described with respect to FIG. 3 may be used to deposit SiO₂ in operation 203, and in some embodiments, in operation 205. If another oxidant is used in operation 205, the PEALD cycle is changed appropriately.

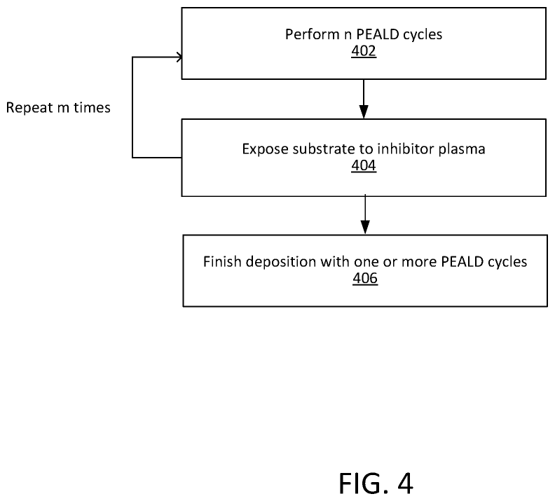

In some embodiments, one or both of operations 203 and 205 may include inhibitor and/or etch operations. FIG. 4 is a process flow diagram illustrating operations in which a gap is filled using periodic inhibitor plasmas. In FIG. 4, n PEALD cycles are performed to deposit silicon oxide, where n is an integer greater or equal to 1. An example of one PEALD cycle is given above with respect to FIG. 3. Then the substrate is exposed to an inhibitor plasma in an operation 404. Examples of gasses use to generate an inhibitor plasma gas may include fluorine-containing compounds such as nitrogen trifluoride (NF₃), molecular nitrogen (N₂), argon (Ar), helium (He), molecular hydrogen (H₂), ammonia (NH₃), amines, diols, diamines, aminoalcohols, thiols or combinations thereof. An inhibitor plasma can enhance bottom-up gapfill by creating a passivated surface and increases a nucleation barrier of deposited ALD films. When the inhibitor plasma interacts with material in a gap, the material at a bottom of the gap receives much less plasma treatment than material located closer to a top portion of the gap or the field because of geometrical shadowing effects. As a result, deposition at the top of the gap is selectively inhibited and deposition in lower portions of the feature proceeds with less inhibition or without being inhibited. As a result, bottom-up fill is enhanced. As indicated in FIG. 4, exposure to the inhibitor plasma occurs once every n PEALD cycles with examples of n being 5-10. Operations 402 and 404 are repeated m times to appropriately shape the deposition profiled and fill the gap. The deposition may then be finished with one or more PEALD cycles in an operation 406. A process as shown in FIG. 4 may be performed to implement operations 203 and 205, or operation 205, as appropriate. An etch operation may be used in addition to or instead of an inhibition operation to shape a profile and provide good gap fill. In some embodiments, operation 205 can involve multiple PEALD-inhibition cycles.

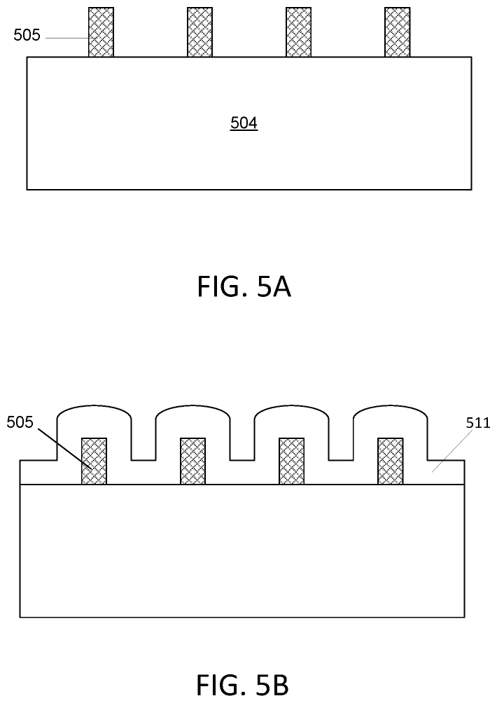

An example of a method of using the low loss PEALD deposition described herein is described below with respect to FIGS. 5-8. A semiconductor substrate including a layer formed into carbon-based features 505, which may be lithographically defined in a previous process, on top of a substrate surface 504, is depicted. The carbon-based features may be formed on a multi-layer stack that may include one or more mask layers and a target layer in some embodiments. One or more barrier layers, cap layers, or etch stop layers may also be included in the multi-layer stack.

A silicon oxide layer 511 is deposited on the carbon-based features 505 as described herein with reference to FIGS. 2-4. This is shown in FIG. 5B. The silicon oxide layer is deposited to a uniform thickness without impacting the width or dimensions of the carbon-based features. A directional etching operation may then be performed to selective remove the oxide layer from the substrate surface and from the top of the carbon-based features, thereby exposing the carbon-based features of the initial pattern, while leaving the oxide layer that is formed on the sidewalls. This is shown in FIG. 5C, with carbon-based features 505 and sidewall silicon oxide spacers 512. An ashing operation may then be performed to selectively remove the carbon-based features 505 while leaving the sidewall silicon oxide spacers 512 oxide film layer forming the sidewalls. FIG. 5D shows the resulting pattern. The number of features of the initial pattern is doubled. By using NO₂ as an oxidant, less carbon is consumed from the carbon-based features. The features and gaps of the resulting pattern have substantially uniform critical. The resulting double pattern may act a mask that is transferred to an un underlying layer, which may be a target layer or another layer in a multi-layer stack.

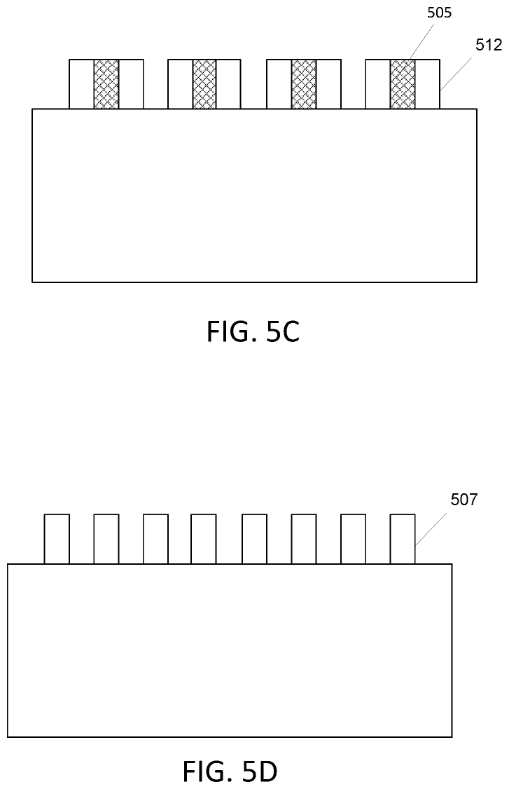

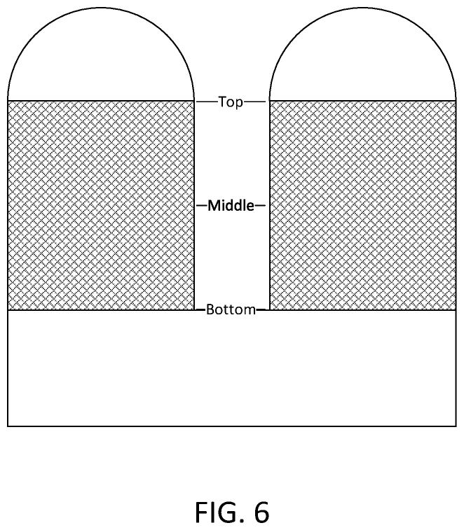

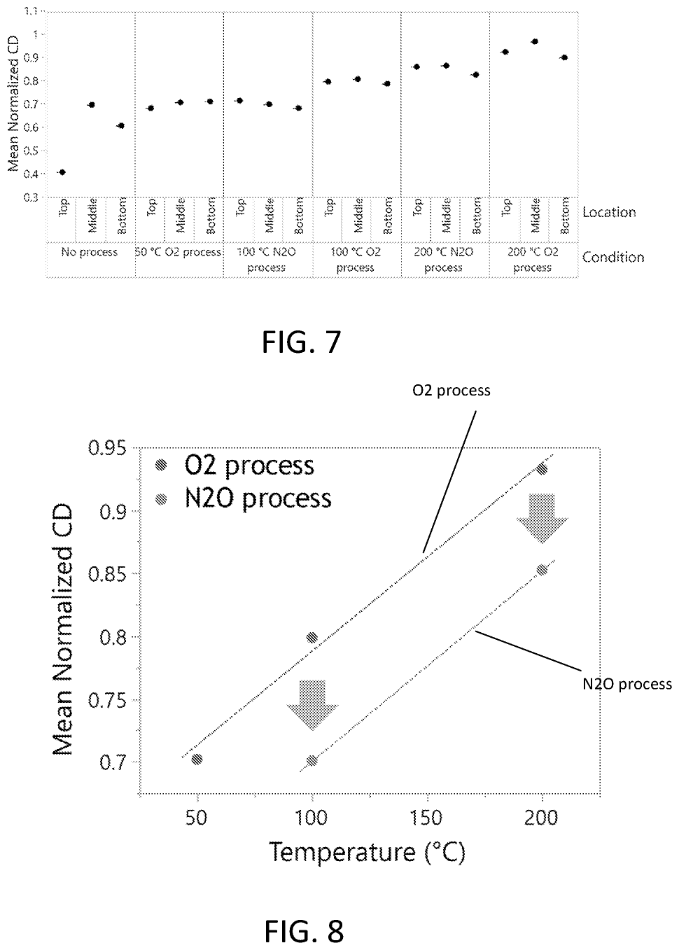

Silicon oxide was deposited on multiple adjacent carbon-based features using PEALD with O₂ or N₂O as oxidant at various temperatures. Critical dimension was measured at the top, middle, and bottom of a gap between two adjacent features as schematically shown in FIG. 6. The HFRF power was 400 W, chamber pressure was 1.8 T. Silicon precursor dose time ranged 0.5-2 s and RF on time (oxidation) ranged from 0.2-0.5 s. FIG. 7 shows the mean normalized CD at 50° C., 100° C., and 200° C. for O₂ and at 100° C. and 200° C. for N₂O, as well as for no process. The mean normalized CD is plotted as a function of temperature for an O₂ process and an N₂O process. As illustrated in FIG. 8, the CD is lower for the N₂O at each temperature, meaning less carbon is lost.

### Apparatus

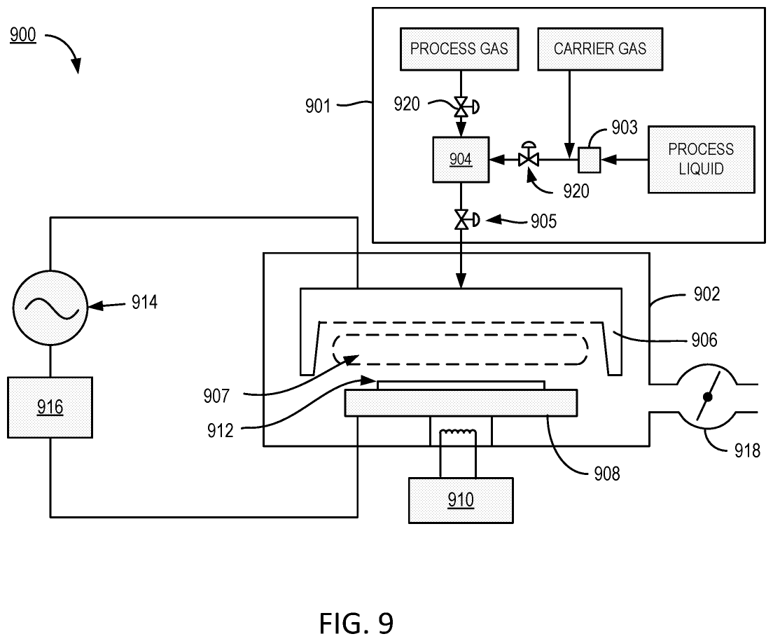

FIG. 9 schematically shows an embodiment of a process station 900 that may be used to deposit material using atomic layer deposition (ALD), which may be plasma enhanced as described above. For simplicity, the process station 900 is depicted as a standalone process station having a process chamber body 902 for maintaining a low-pressure environment. However, it will be appreciated that a plurality of process stations 900 may be included in a common process tool environment. Further, it will be appreciated that, in some embodiments, one or more hardware parameters of process station 900, including those discussed in detail below, may be adjusted programmatically by one or more computer controllers.

Process station 900 fluidly communicates with reactant delivery system 901 for delivering process gases to a distribution showerhead 906. Reactant delivery system 901 includes a mixing vessel 904 for blending and/or conditioning process gases for delivery to showerhead 906. One or more mixing vessel inlet valves 920 may control introduction of process gases to mixing vessel 904. Similarly, a showerhead inlet valve 905 may control introduction of process gasses to the showerhead 906.

Some reactants, like BTBAS, may be stored in liquid form prior to vaporization at and subsequent delivery to the process station. For example, the embodiment of FIG. 9 includes a vaporization point 903 for vaporizing liquid reactant to be supplied to mixing vessel 904. In some embodiments, vaporization point 903 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 903 may be heat traced. In some examples, mixing vessel 904 may also be heat traced. In one non-limiting example, piping downstream of vaporization point 903 has an increasing temperature profile extending from approximately 100° C. to approximately 150° C. at mixing vessel 904.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 903. In one scenario, a liquid injector may be mounted directly to mixing vessel 904. In another scenario, a liquid injector may be mounted directly to showerhead 906.

In some embodiments, a liquid flow controller upstream of vaporization point 903 may be provided for controlling a mass flow of liquid for vaporization and delivery to process station 900. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 906 distributes process gases toward substrate 912. In the embodiment shown in FIG. 9, substrate 912 is located beneath showerhead 906, and is shown resting on a pedestal 908. It will be appreciated that showerhead 906 may have any suitable shape and may have any suitable number and arrangement of ports for distributing processes gases to substrate 912.

In some embodiments, a microvolume 907 is located beneath showerhead 906. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 908 may be raised or lowered to expose substrate 912 to microvolume 907 and/or to vary a volume of microvolume 907. For example, in a substrate transfer phase, pedestal 908 may be lowered to allow substrate 912 to be loaded onto pedestal 908. During a deposition process phase, pedestal 908 may be raised to position substrate 912 within microvolume 907. In some embodiments, microvolume 907 may completely enclose substrate 912 as well as a portion of pedestal 908 to create a region of high flow impedance during a deposition process.

Optionally, pedestal 908 may be lowered and/or raised during portions the deposition process to modulate process pressure, reactant concentration, etc., within microvolume 907. In one scenario where process chamber body 902 remains at a base pressure during the deposition process, lowering pedestal 908 may allow microvolume 907 to be evacuated. Example ratios of microvolume to process chamber volume include, but are not limited to, volume ratios between 1:900 and 1:10. It will be appreciated that, in some embodiments, pedestal height may be adjusted programmatically by a suitable computer controller.

In another scenario, adjusting a height of pedestal 908 may allow a plasma density to be varied during plasma activation and/or treatment cycles included in the deposition process. At the conclusion of the deposition process phase, pedestal 908 may be lowered during another substrate transfer phase to allow removal of substrate 912 from pedestal 908.

While the example microvolume variations described herein refer to a height-adjustable pedestal, it will be appreciated that, in some embodiments, a position of showerhead 906 may be adjusted relative to pedestal 908 to vary a volume of microvolume 907. Further, it will be appreciated that a vertical position of pedestal 908 and/or showerhead 906 may be varied by any suitable mechanism within the scope of the present disclosure. In some embodiments, pedestal 908 may include a rotational axis for rotating an orientation of substrate 912. It will be appreciated that, in some embodiments, one or more of these example adjustments may be performed programmatically by one or more suitable computer controllers.

Returning to the embodiment shown in FIG. 9, showerhead 906 and pedestal 908 electrically communicate with RF power supply 914 and matching network 916 for powering a plasma. In some embodiments, the plasma energy may be controlled by controlling one or more of a process station pressure, a gas concentration, an RF source power, an RF source frequency, and a plasma power pulse timing. For example, RF power supply 914 and matching network 916 may be operated at any suitable power to form a plasma having a desired composition of radical species. Examples of suitable powers are included above. Likewise, RF power supply 914 may provide RF power of any suitable frequency. In some embodiments, RF power supply 914 may be configured to control high- and low-frequency RF power sources independently of one another. Example low-frequency RF frequencies may include, but are not limited to, frequencies between 50 kHz and 900 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 908 may be temperature controlled via heater 910. Further, in some embodiments, pressure control for deposition process station 900 may be provided by butterfly valve 918. As shown in the embodiment of FIG. 9, butterfly valve 918 throttles a vacuum provided by a downstream vacuum pump (not shown). However, in some embodiments, pressure control of process station 900 may also be adjusted by varying a flow rate of one or more gases introduced to process station 900.

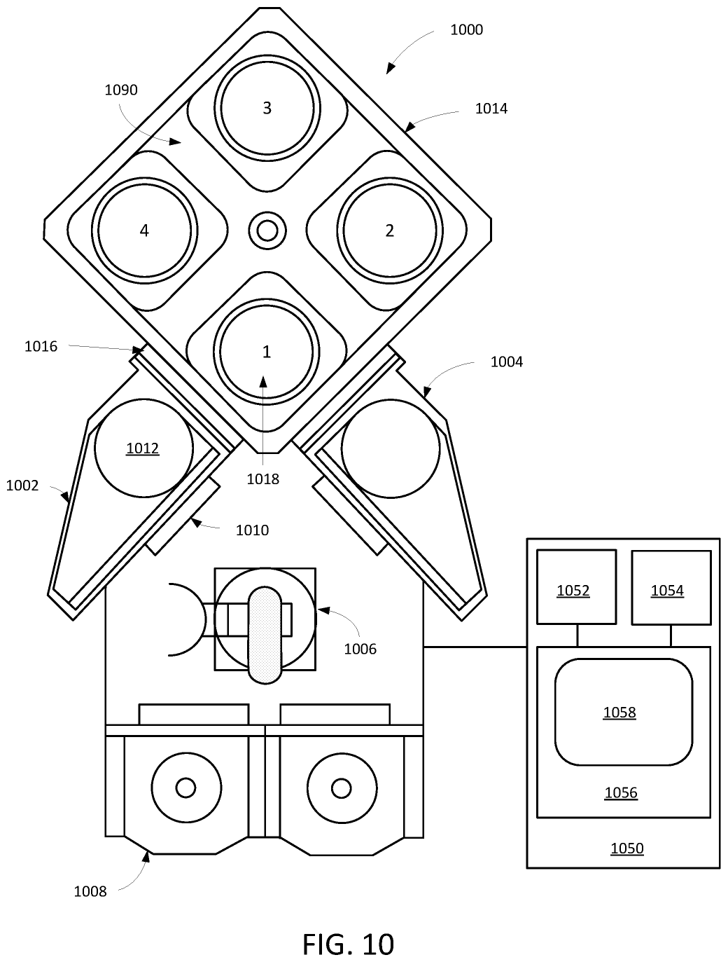

FIG. 10 shows a schematic view of an embodiment of a multi-station processing tool 1000 with an inbound load lock 1002 and an outbound load lock 1004, either or both of which may comprise a remote plasma source. A robot 1006, at atmospheric pressure, is configured to move wafers from a cassette loaded through a pod 1008 into inbound load lock 1002 via an atmospheric port 1010. A wafer is placed by the robot 1006 on a pedestal 1012 in the inbound load lock 1002, the atmospheric port 1010 is closed, and the load lock is pumped down. Where the inbound load lock 1002 comprises a remote plasma source, the wafer may be exposed to a remote plasma treatment in the load lock prior to being introduced into a processing chamber 1014. Further, the wafer also may be heated in the inbound load lock 1002 as well, for example, to remove moisture and adsorbed gases. Next, a chamber transport port 1016 to processing chamber 1014 is opened, and another robot (not shown) places the wafer into the reactor on a pedestal of a first station shown in the reactor for processing. While the embodiment depicted in FIG. 10 includes load locks, it will be appreciated that, in some embodiments, direct entry of a wafer into a process station may be provided.

The depicted processing chamber 1014 comprises four process stations, numbered from 1 to 4 in the embodiment shown in FIG. 10. Each station has a heated pedestal (shown at 1018 for station 1), and gas line inlets. It will be appreciated that in some embodiments, each process station may have different or multiple purposes. While the depicted processing chamber 1014 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 10 also depicts an embodiment of a wafer handling system 1090 for transferring wafers within processing chamber 1014. In some embodiments, wafer handling system 1090 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc.

In some embodiments, system controller 1050 controls all the activities of process tool 1000. System controller 1050 executes system control software 1058 stored in mass storage device 1054, loaded into memory device 1056, and executed on processor 1052. System control software 1058 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 1000. System control software 1058 may be configured in any suitable way. For example, various process tool component subroutines or control objects may be written to control operation of the process tool components necessary to carry out various process tool processes in accordance with the disclosed methods. System control software 1058 may be coded in any suitable computer readable programming language.

In some embodiments, system control software 1058 may include input/output control (IOC) sequencing instructions for controlling the various parameters described above. For example, each phase of a PEALD process may include one or more instructions for execution by system controller 1050. The instructions for setting process conditions for a PEALD process phase may be included in a corresponding PEALD recipe phase. In some embodiments, the PEALD recipe phases may be sequentially arranged, so that all instructions for a PEALD process phase are executed concurrently with that process phase.

Other computer software and/or programs stored on mass storage device 1054 and/or memory device 1056 associated with system controller 1050 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1018 and to control the spacing between the substrate and other parts of process tool 1000.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, the STRIKER® product family, and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired. In some embodiments, single station chambers are provided.

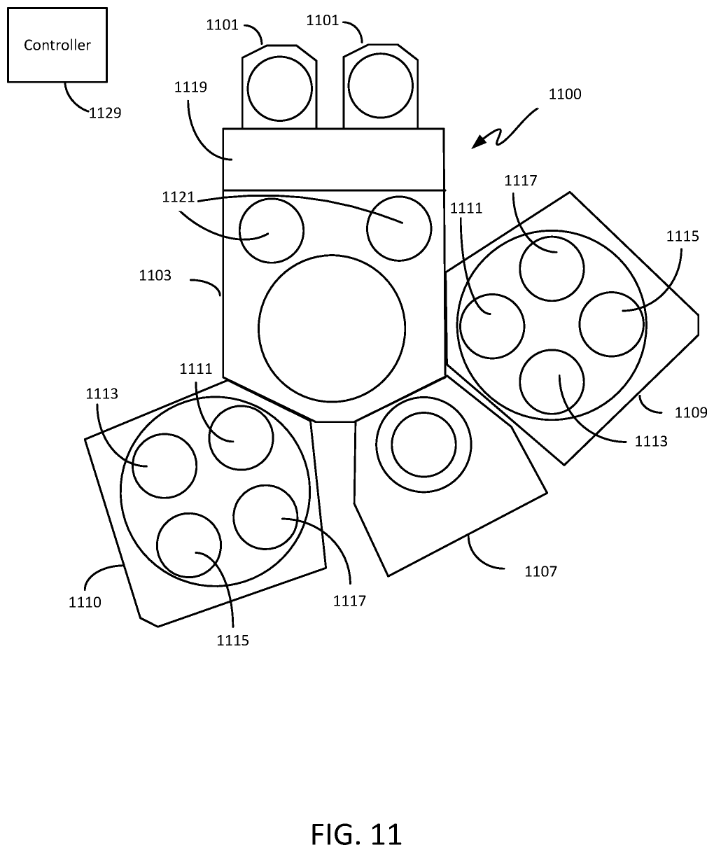

FIG. 11 is a block diagram of a processing system suitable for the deposition processes described herein in accordance with certain embodiments. The system 1100 includes a transfer module 1103. The transfer module 1103 provides a clean, pressurized environment to minimize risk of contamination of substrates being processed as they are moved between various reactor modules. Mounted on the transfer module 1103 are two multi-station reactors 1109 and 1110, each capable of performing atomic layer deposition (ALD) and/or chemical vapor deposition (CVD) according to certain embodiments. Reactors 1109 and 1110 may include multiple stations 1111, 1113, 1115, and 1117 that may sequentially or non-sequentially perform operations in accordance with disclosed embodiments. The stations may include a heated pedestal or substrate support, one or more gas inlets or showerhead or dispersion plate. As indicated above, in some embodiments, a single station reactor is used.

Also mounted on the transfer module 1103 may be one or more single or multi-station modules 1107 capable of performing plasma or chemical (non-plasma) pre-cleans, or any other processes described in relation to the disclosed methods. The module 1107 may in some cases be used for various treatments to, for example, prepare a substrate for a deposition process. The module 1107 may also be designed/configured to perform various other processes such as etching or polishing. The system 1100 also includes one or more wafer source modules 1101, where wafers are stored before and after processing. An atmospheric robot (not shown) in the atmospheric transfer chamber 1119 may first remove wafers from the source modules 1101 to loadlocks 1121. A wafer transfer device (generally a robot arm unit) in the transfer module 1103 moves the wafers from loadlocks 1121 to and among the modules mounted on the transfer module 1103.

In various embodiments, a system controller 1129 is employed to control process conditions during deposition. The controller 1129 will typically include one or more memory devices and one or more processors. A processor may include a CPU or computer, analog and/or digital input/output connections, stepper motor controller boards, etc.

The controller 1129 may control all the activities of the deposition apparatus. The system controller 1129 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1129 may be employed in some embodiments.

Typically there will be a user interface associated with the controller 1129. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 1129. The signals for controlling the process are output on the analog and digital output connections of the deposition apparatus 1100.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 1129 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1129, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems and apparatus of the present embodiments. Accordingly, the present embodiments are to be considered as illustrative and not restrictive, and the embodiments are not to be limited to the details given herein.

What is claimed is:

1. A method comprising:
providing a substrate having carbon-based features thereon, the carbon-based features having exposed sidewall surfaces and being separated by gaps;
depositing a silicon oxide liner film in the gaps by a plasma enhanced atomic layer deposition (PEALD) process that comprises multiple cycles of (a) introducing a silicon-containing reactant into a reaction chamber having the substrate therein, and allowing the first reactant to adsorb onto substrate surfaces; (b) generating oxygen radicals from N₂O, and (c) exposing the adsorbed silicon-containing reactant to the oxygen radicals to form the silicon oxide liner film in the gaps,
wherein the substrate temperature during deposition is at least 100° C.

2. The method of claim 1, further comprising, after depositing the silicon oxide liner film in the gaps, depositing silicon oxide film in the gaps by PEALD using a reaction between the silicon-containing reactant and oxygen (O₂).

3. The method of claim 1, further comprising at least partially filling the gaps with silicon oxide by PEALD using a reaction between the silicon-containing reactant and N₂O.

4. The method of claim 1, wherein the substrate temperature during deposition is at least 150° C.

5. The method of claim 1, wherein the substrate temperature during deposition is at least 200° C.

6. The method of claim 1, further comprising, during PEALD deposition, periodically exposing the substrate to an inhibition plasma.

7. The method of claim 6, wherein the inhibition plasma is generated from an inhibition gas generated from one of a fluorine-containing compound, molecular nitrogen (N₂), argon (Ar), helium (He), molecular hydrogen (H₂), ammonia (NH₃), an amine, a diol, an aminoalcohol, a thiol or a combination thereof.

8. The method of claim 1, wherein the silicon-containing reactant is an aminosilane.

9. The method of claim 8, wherein the aminosilane has two or more amine groups attached to the central silicon atom.

10. A method comprising:
(a) providing a substrate having carbon-based features thereon, the carbon-based features having exposed sidewall surfaces and being separated by gaps;
(b) performing multiple cycles of a (i) introducing a silicon-containing reactant into a reaction chamber having the substrate therein and allowing the first reactant to adsorb onto substrate surfaces, (ii) generating oxygen radicals from N₂O, and (iii) exposing the adsorbed silicon-containing reactant to the oxygen radicals to form a silicon oxide liner film in the gaps;
(c) after (b) exposing the gaps to an inhibition plasma.

11. The method of claim 10, further comprising (d) after (c), filling the gap with a silicon oxide film.

12. The method of claim 11, wherein (d) comprises using a plasma generated from oxygen (O₂) as an oxidant.

13. The method of claim 12, wherein (d) comprises using a plasma generated from N₂O and O₂ as an oxidant.

14. The method of claim 11, wherein (d) is performed at a different substrate temperature than (b).

15. The method of claim 11, wherein (d) is performed at the same substrate temperature as (b).

16. The method of claim 10, further comprising after (c), repeating (b).

17. The method of claim 10, further comprising after (c), repeating (b) and (c) one or more times.

18. The method of claim 10, wherein the substrate temperature throughout the process is at least 100° C.

19. The method of claim 10, wherein the substrate temperature throughout the process is at least 150° C.

20. The method of claim 10, wherein the substrate temperature throughout the process is at least 200° C.
